(19) United States
(12) Patent Application Publication
(10) Pub. No.: US 2024/0407189 A1
(43) Pub. Date: Dec. 5, 2024

(54) ORGANIC LIGHT EMITTING ELEMENT

(71) Applicant: CANON KABUSHIKI KAISHA, Tokyo (JP)

(72) Inventor: KOJI ISHIZUYA, Kanagawa (JP)

(21) Appl. No.: 18/674,695

(22) Filed: May 24, 2024

(30) Foreign Application Priority Data
May 31, 2023 (JP) 2023-090274

(51) Int. Cl. H10K 50/814

(52) U.S. Cl. CPC H10K 50/814

(57) ABSTRACT

An organic light emitting element includes a substrate having a first surface, a conductive layer on the first surface, an insulating layer, a first electrode, an organic compound layer, and a second electrode, in this order. The conductive layer includes a recess portion. The first electrode and the conductive layer are electrically connected to each other at least in a part of the recess portion.

### BACKGROUND

### Field

The present disclosure relates to an organic light emitting element.

### Description of the Related Art

An organic light emitting element (hereinafter, will also be referred to as an “organic electroluminescence (EL) device” or an “organic device”) is a light emitting element including a pair of electrodes, and an organic compound layer including a light emitting layer between the pair of electrodes. The organic light emitting element is characterized by low drive voltage, a broad range of light emission wavelengths, and high-speed responsivity, and by providing a thin and lightweight light emitting device. Taking advantages of these characteristics, the organic light emitting element is used in a flat-panel display, an illumination device, and a head-mounted display (HMD), for example.

On the other hand, it is known that an increase in brightness and power saving of the organic light emitting element can be achieved by optimizing the optical distance between the light emitting layer and a reflective film of the organic light emitting element.

Japanese Patent Application Laid-Open No. 2019-121604 discusses an organic light emitting element in which a predetermined potential is applied to a lower electrode by the lower electrode and a reflective electrode connecting with each other at an end portion of the reflective electrode with an insulating layer arranged between the lower electrode and the reflective electrode.

The connection portion of the lower electrode and the reflective electrode is, however, provided at a distance from a light emitting unit in the organic light emitting element discussed in Japanese Patent Application Laid-Open No. 2019-121604, so that a potential difference can be generated between the lower electrode and the reflective electrode due to a voltage drop of the lower electrode, resulting in a lower reliability of the insulating layer arranged between the lower electrode and the reflective electrode.

### SUMMARY

In view of the above-described issue, the present disclosure is directed to providing an organic light emitting element with a reduced voltage drop of a lower electrode.

According to some embodiments, an organic light emitting element can include a substrate having a first surface, a conductive layer on the first surface, an insulating layer, a first electrode, an organic compound layer, and a second electrode, in this order. The conductive layer can include a recess portion. The first electrode and the conductive layer are electrically connected to each other at least in a part of the recess portion.

Further features of the present disclosure will become apparent from the following description of exemplary embodiments with reference to the attached drawings.

### BRIEF DESCRIPTION OF THE DRAWINGS

FIG. 1A is a plan view illustrating an organic light emitting element according to a first exemplary embodiment of the present disclosure. FIG. 1B is a cross-sectional view illustrating the organic light emitting element according to the first exemplary embodiment. FIG. 1C is a cross-sectional view illustrating the organic light emitting element according to the first exemplary embodiment.

FIGS. 2A to 2G are diagrams illustrating a manufacturing procedure of the organic light emitting element according to the first exemplary embodiment.

FIG. 3 is a cross-sectional view illustrating an organic light emitting element according to a second exemplary embodiment.

FIGS. 4A and 4B are cross-sectional views illustrating an organic light emitting element according to a third exemplary embodiment.

FIGS. 5A and 5B are cross-sectional views illustrating an organic light emitting element according to a fourth exemplary embodiment.

FIG. 6 is a cross-sectional view illustrating an organic light emitting element according to a fifth exemplary embodiment.

FIG. 7 is a cross-sectional view illustrating an organic light emitting element according to a sixth exemplary embodiment.

FIG. 8 is a cross-sectional view illustrating an organic light emitting element according to a seventh exemplary embodiment.

FIG. 9 is a schematic diagram illustrating an example of a display apparatus according to an exemplary embodiment.

FIGS. 10A and 10B are schematic diagrams illustrating examples of an imaging apparatus according to exemplary embodiments.

FIG. 11A is a schematic diagram illustrating an example of a display apparatus according to an exemplary embodiment. FIG. 11B is a schematic diagram illustrating an example of a foldable display apparatus.

FIG. 12A is a schematic diagram illustrating an example of an illumination apparatus according to an exemplary embodiment. FIG. 12B is a schematic diagram illustrating an example of an automobile including a vehicle lighting device according to an exemplary embodiment.

FIG. 13A is a schematic diagram illustrating an example of a wearable device according to an exemplary embodiment. FIG. 13B is a schematic diagram illustrating an example of a wearable device having a configuration including an imaging apparatus according to an exemplary embodiment.

FIG. 14A is a schematic diagram illustrating an example of an image forming apparatus according to an exemplary embodiment. FIGS. 14B and 14C are schematic diagrams illustrating examples of an exposure light source of an image forming apparatus according to exemplary embodiments.

FIG. 15 is a cross-sectional view illustrating a conventional organic light emitting element.

### DESCRIPTION OF THE EMBODIMENTS

Hereinafter, various exemplary embodiments, features, and aspects of the present disclosure will be described in detail with reference to the accompanying drawings. The following exemplary embodiments are not intended to limit the disclosure set forth in the appended claims. A plurality of features is described in the exemplary embodiments, but not all of the plurality of features are used in the disclosure. In addition, any combination of the plurality of features can be made. Furthermore, in the accompanying drawings, the same or similar components are assigned the same reference numerals, and the redundant description will be omitted.

In the specification of the present application, in a case where the expression containing “on a substrate” or “under a substrate” is used, “on a substrate” represents a state of being on a side of the substrate on which a conductive layer is arranged, and “under a substrate” represents a state of being on the opposite side to the conductive layer side. In a case where a conductive layer is arranged “on” a substrate, the substrate and the conductive layer do not necessarily contact each other.

In this specification, in the case of referring to an organic light emitting element with a specific light emission color among a plurality of organic light emitting elements, a suffix is added to a reference numeral like an organic light emitting element 100“r”, and in the case of referring to any one of the organic light emitting elements, the one organic light emitting element is simply represented as an organic light emitting element “100”. The same applies to other components.

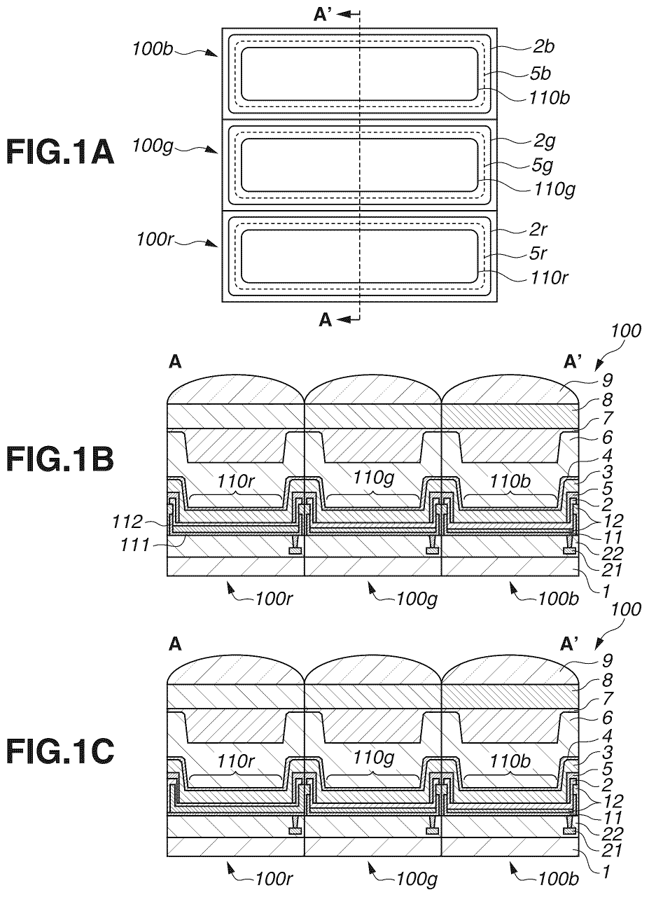

An organic light emitting element 100 according to a first exemplary embodiment will be described with reference to FIGS. 1A and 1B. FIG. 1A is a plan view illustrating the organic light emitting element 100 according to the first exemplary embodiment of the present disclosure. FIG. 1B is a cross-sectional view illustrating the organic light emitting element 100 taken along an A-A′ line in FIG. 1A. FIG. 1C illustrates an organic light emitting element 100 according to a modified example of the first exemplary embodiment.

The organic light emitting element 100 according to the present exemplary embodiment of the present disclosure includes, on a first surface of a substrate 1, a conductive layer 11, an insulating layer 12, a first electrode 2, an organic compound layer 3, and a second electrode 4 in this order.

The substrate 1 is formed of a material capable of supporting the conductive layer 11, the insulating layer 12, the first electrode 2, the organic compound layer 3, and the second electrode 4. Specifically, the substrate 1 can be a semiconductor substrate, such as a silicon substrate, or a resin substrate. In other embodiments, a switching element (not illustrated), such as a transistor, a wiring layer 21, or an interlayer insulating layer 22, is formed on the substrate 1.

The conductive layer 11 has a function of supplying current to the first electrode 2. The conductive layer 11 can directly connect to a power source, or connect to a power source via the wiring layer 21. Further, current can be supplied to the conductive layer 11 from a power source via a transistor (not illustrated). In addition, the conductive layer 11 can function as a reflective layer that reflects light emitted from the organic compound layer 3, and emits the reflected light in the direction of the second electrode 4.

For this reason, it is desirable that the conductive layer 11 is formed of a conductive material, and has a light reflectance of 80% or more. Specifically, the conductive layer 11 is desirably formed of a metal material, such as aluminum (Al), silver (Ag), platinum (Pt), nickel (Ni), or titanium (Ti), an alloy obtained by adding a substance or substances, such as silicon (Si), copper (Cu), Ni, neodymium (Nd), and/or Ti, to the metal material, or a metal compound, such as a titanium nitride (TiN). The conductive layer 11 can be formed of a single layer or a plurality of layers.

The type of the first electrode 2 is not specifically limited as long as the first electrode 2 can pass light emitted from the organic compound layer 3 toward the substrate 1, but the first electrode 2 is desirably a transparent electrode from the viewpoint of light emission efficiency. Specifically, examples of the first electrode 2 include a thin film made of a conductive oxide material, such as an indium tin oxide (ITO) or an indium zinc oxide (IZO), or a conductive material, such as metal including Al, Ag, and Pt, an alloy, or a metal oxide.

The organic compound layer 3 is arranged on the first electrode 2, and can be formed using a known method, such as a vapor deposition method, a spin coating method, or an inkjet method. The organic compound layer 3 includes at least a light emitting layer. The light emitting layer includes at least one light emitting material. Examples of the light emitting material include a blue light emitting material, a green light emitting material, and a red light emitting material. The light emitting material can be a fluorescent material, a delayed fluorescent material, and a phosphorescent material. One light emitting layer can include one type of a light emitting material, or two or more types of light emitting materials.

The organic compound layer 3 can be formed of a single layer or a plurality of layers. In a case where the organic compound layer 3 includes a plurality of light emitting layers, the light emitting layers can be adjacently stacked, or be provided via a different layer. In a case where the organic compound layer 3 includes a different layer other than the light emitting layers, examples of the different layer include a hole-injecting layer, a hole transport layer, an electron blocking layer, a hole blocking layer, an electronic transport layer, an electron-injection layer, and a charge generation layer.

The second electrode 4 is arranged on the organic compound layer 3, and is made of a material through which at least part of light emitted by the organic compound layer 3 can pass. Specifically, examples of the material include a transparent conductive oxide material, such as an ITO or an IZO, metal, such as Al, Ag, or gold (Au), alkali metal/, such as lithium (Li) or cesium (Cs), alkali earth metal, such as magnesium (Mg), calcium (Ca), or barium (Ba), and a semi-transmissive reflective material as a thin film made of an alloy material containing these types of metal. It is especially desirable that the second electrode 4 is made of Ag or an alloy containing Mg and Ag. In addition, the second electrode 4 can a single layer and a plurality of layers as long as light can pass through the second electrode 4.

In the present exemplary embodiment, the first electrode 2 can be a negative electrode, and the second electrode 4 a positive electrode. Further, the first electrode 2 can be a positive electrode, and the second electrode 4 a negative electrode. Holes are injected from a positive electrode and electrons are injected from a negative electrode. These re-combinations in an organic compound layer (especially in the organic compound layer 3) cause the organic light emitting element 100 to emit light.

The insulating layer 12 is arranged between the conductive layer 11 and the first electrode 2. The insulating layer 12 is desirably made of a material through which light can pass. Specifically, examples of the material include an inorganic material, such as a silicon nitride, a silicon oxynitride, and a silicon oxide, and an organic material, such as an acrylic resin, a polyimide resin, an epoxy resin, and a silicon resin. The insulating layer 12 can be formed using a known method, such as a sputtering method or a chemical vapor deposition method (CVD method).

The layer thickness of the insulating layer 12 can be adjusted in such a manner that can extract light emitted by the organic compound layer 3 efficiently. The layer thickness refers to the thickness of a layer in a direction vertical to the first surface in a cross section passing through the substrate 1, the insulating layer 12, and the organic compound layer 3. Varying the layer thickness of the insulating layer 12 allows adjustment of the light emission efficiency and the color purity of each of a plurality of organic light emitting elements.

Especially in the organic light emitting element 100 according to the present exemplary embodiment, part of light emitted from the organic compound layer 3 is reflected on the conductive layer 11. In a case where light emitted by the organic compound layer 3 and the reflected light interfere with each other to intensify each other, the organic light emitting element 100 according to the present exemplary embodiment can be said to have an optical resonator structure. Specifically, among light rays emitted by the organic compound layer 3 toward the second electrode 4 and emitted from the organic compound layer 3, light rays reflected on the conductive layer 11 interface with each other in the organic compound layer 3 to intensify each other. For this reason, an organic light emitting element with an optical resonator structure is an organic light emitting element excellent in light emission efficiency and color purity.

In a case where the organic light emitting element 100 according to the present exemplary embodiment includes an organic light emitting element 100r and an organic light emitting element 100g, heights vertical to the first surface of the insulating layer 12r and the insulating layer 12g can be different from each other in the cross section across the substrate 1, the insulating layer 12, and the organic compound layer 3. In a case where the organic light emitting element 100 according to the present exemplary embodiment further includes an organic light emitting element 100b, heights vertical to the first surface of the insulating layer 12r, the insulating layer 12g, and the insulating layer 12b can be different from each other in the cross section passing through the substrate 1, the insulating layer 12, and the organic compound layer 3.

The organic light emitting element 100 according to the present exemplary embodiment can further include at least one of an insulator portion 5 on the first electrode 2, a sealing layer 6 on the second electrode 4, a planarization layer 7, a color filter layer 8, or an optical member 9.

The insulator portion 5 has a function of covering at least the end portion of the first electrode 2, and insulating the first electrode 2 from a first electrode included in an adjacent organic light emitting element. The insulator portion 5 can be formed of an inorganic material, such as a silicon nitride, a silicon oxynitride, or a silicon oxide, or an organic material, such as an acrylic resin, a polyimide resin, an epoxy resin, or a silicon resin. The insulator portion 5 can be formed using a known method, such as the sputtering method or the CVD method.

The sealing layer 6 can be arranged on the second electrode 4, and has a function of protecting the organic light emitting element 100 from air or moisture intrusion. The material of the sealing layer 6 is, not specifically limited, desirably a material that has transparency and can prevent oxygen or moisture intrusion from the outside. Specifically, examples of the material include an inorganic material, such as a silicon nitride, a silicon oxynitride, a silicon oxide, an aluminum oxide, and a titanium oxide, and an organic material, such as an acrylic resin, a polyimide resin, an epoxy resin, and a silicon resin.

The sealing layer 6 can be formed using a known method, such as the CVD method, an atomic layer deposition method (ALD method), or the sputtering method.

The sealing layer 6 can be either a single layer or a plurality of layers as long as the sealing layer 6 has the above-described function.

Especially in a case where the sealing layer 6 is formed of a plurality of layers, the sealing layer 6 can have a stacked structure including an inorganic material or inorganic materials alone or including an organic material or organic materials alone, or can have a stacked structure including the inorganic material(s) and the organic material(s). In addition, the sealing layer 6 can be formed over a plurality of organic light emitting elements.

The planarization layer 7 can be formed on the sealing layer 6. The planarization layer 7 is provided for the purpose of reducing unevenness of a lower layer. The material of the planarization layer 7 is not specifically limited, but the planarization layer 7 can be formed of an inorganic material or an organic material, and in a case where the planarization layer 7 is formed of an organic material, the organic material can be either a low molecular material or a high molecular material.

The planarization layer 7 is desirably formed through a wet process, such as a spin coating method, a dip coating method, a slit coating method, or a blade coating method. Forming the planarization layer 7 through a wet process makes it easy to planarize the surface of the planarization layer 7 as its light emission surface. The planarization layer 7 formed through a wet process is desirably cured by heating or ultraviolet (UV) radiation after the formation. The planarization layer 7 can be formed over a plurality of organic light emitting elements.

The color filter layer 8 can be provided on the light emission side of the organic light emitting element 100, and is desirably provided on the planarization layer 7. In a case where the organic light emitting element 100 according to the present exemplary embodiment includes a plurality of organic light emitting elements, wavelengths of light rays passing through a color filter layer 8r included in the organic light emitting element 100r and a color filter layer 8g included in the organic light emitting element 100g can be different from each other or the same. In a case where the organic light emitting element 100 further includes the organic light emitting element 100b, the wavelength of light passing through a color filter layer 8b included in the organic light emitting element 100b can be different from the wavelengths of light rays passed by the color filter layers 8r and 8g, or the same as the wavelengths of light rays passing through the color filter layers 8r and 8g.

The color filter layer 8 can be formed by applying a color resist to a foundation layer, such as the planarization layer 7, and then performing patterning thereof using photolithography. The color resist is formed of a photocurable resin, for example, and a pattern is formed by curing a portion irradiated with ultraviolet, for example.

The optical member 9 can be provided on the light emission side of the organic light emitting element 100, and can be provided on or under the color filter layer 8. The optical member 9 can be a lens. The shape of the optical member 9 is, not specifically limited, a convex shape curved toward the organic compound layer 3 or a convex shape curved in the direction opposite to the organic compound layer 3. When the optical member 9 is a lens, the optical member 9 will be referred to as a microlens in some cases. The microlens can be a spherical microlens, an aspherical microlens, or an asymmetric microlens.

The optical member 9 is formed of a material with optical transparency. Specifically, for example, the optical member 9 is formed of an organic material, such as an acrylic resin, an epoxy resin, or a silicon resin, or an inorganic material, such as a silicon nitride, a silicon oxynitride, or a silicon oxide.

In a case where the optical member 9 has a convex shape curved in the direction opposite to the organic compound layer 3, a material with a refractive index lower than that of the material of the optical member 9 is arranged on the light emission side of the optical member 9. Gas, such as air or nitrogen, a material with a low refractive index, such as silica aerogel, or a vacuum state is especially desirable. In a case where the optical member 9 has a convex shape curved toward the organic compound layer 3, a material with a refractive index higher than that of the material of the lens is arranged on the light emission side.

In the organic light emitting element 100 according to the present exemplary embodiment, the organic light emitting elements 100r, 100g, and 100b can be regarded as subpixels, and a pixel formed of a plurality of subpixels can be regarded as one main pixel. A pixel array of subpixels can be a stripe array, a delta array, or a Bayer array, for example. A delta array is especially desirable because a circular lens can be easily arranged within a display plane. A plurality of main pixels provided within a display plane provides a high-definition display apparatus.

Subsequently, the organic light emitting element 100 according to the first exemplary embodiment of the present disclosure will be described in detail.

In the organic light emitting element 100 according to the present exemplary embodiment of the present disclosure, the conductive layer 11 has a recess portion 110, and the insulating layer 12 and the first electrode 2 are arranged on the recess portion 110. In this state, the first electrode 2 and the conductive layer 11 are electrically connected at least in a part of the recess portion 110. Examples of the configuration in which the first electrode 2 and the conductive layer 11 are electrically connected include a configuration in which the first electrode 2 and the conductive layer 11 are connected via another layer, and a configuration in which the first electrode 2 and the conductive layer 11 are directly connected. In addition, the conductive layer 11 can be continuously formed in the recess portion 110.

In this specification, the recess portion 110 in the conductive layer 11 has a first surface 111 corresponding to the bottom surface of the recess portion 110, and a second surface 112 inclining relative to the first surface 111. The angle formed between the first surface 111 and the second surface 112 can be a sharp angle, an obtuse angle, or a right angle. From the viewpoint of manufacturing, the angle formed between the first surface 111 and the second surface 112 can be a right angle or an obtuse angle.

In the organic light emitting element 100 according to the present exemplary embodiment of the present disclosure in this state, the first electrode 2 and the conductive layer 11 can be electrically connected to each other on the second surface 112 of the recess portion 110. In a planar view with respect to the first surface 111, the first electrode 2 and the conductive layer 11 can be electrically connected to each other at a position on the first surface 111 of the recess portion 110 that overlaps the insulator portion 5. From the viewpoint of manufacturing, it is desirable that the first electrode 2 and the conductive layer 11 are electrically connected to each other on the second surface 112 of the recess portion 110.

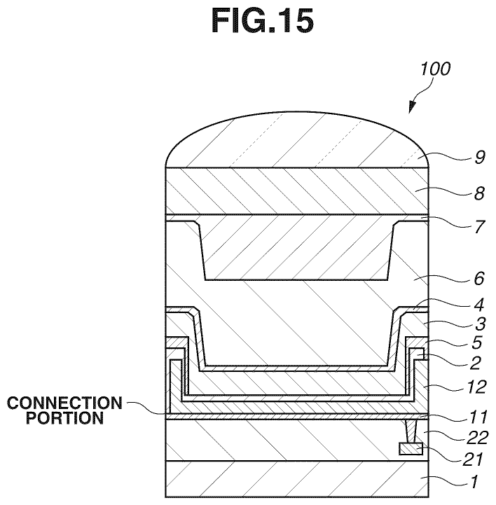

A difference between a conventional organic light emitting element and the organic light emitting element according to the present exemplary embodiment of the present disclosure will now be described with reference to FIGS. 1A to 1C and 15. FIG. 15 is a cross-sectional view illustrating a conventional organic light emitting element. In the conventional organic light emitting element, with the insulating layer 12 arranged between the conductive layer 11 and the first electrode 2, the first electrode 2 contacts the conductive layer 11 outside the recess portion 110, specifically, at an end portion of the conductive layer 11.

Thus, the first electrode 2 and the conductive layer 11 connect to each other at a position farther from its light emitting unit. Such a configuration of a conventional organic light emitting element can produce a difference between the voltage of the first electrode 2 near the connection portion at which the first electrode 2 and the conductive layer 11 are connected to each other, and the voltage of the first electrode 2 in the light emitting unit. In other words, this configuration can produce a difference between the voltage of the first electrode 2 in the light emitting unit and the voltage of the conductive layer 11. As a result, the difference between the voltage of the first electrode 2 and the voltage of the conductive layer 11 can lead to a lower reliability of the insulating layer 12, resulting in, specifically, insulation breakdown of the insulating layer 12.

On the other hand, the organic light emitting element 100 according to the present exemplary embodiment of the present disclosure has a configuration in which the first electrode 2 and the conductive layer 11 are electrically connected to each other at least in a part of the recess portion 110. Thus, compared with the conventional organic light emitting element, the connection portion of the first electrode 2 and the conductive layer 11 is arranged at a position closer to the light emitting unit. As a result, the configuration of the organic light emitting element 100 achieves a reduced voltage drop of the first electrode 2, providing reduction of the breakdown of the insulating layer 12 attributed to the difference between the voltage of the first electrode 2 and the voltage of the conductive layer 11.

An organic light emitting element according to a modified example of the first exemplary embodiment will now be described. When the organic light emitting element 100 according to the present exemplary embodiment includes a plurality of organic light emitting elements, not all the organic light emitting elements need to have the structure of the organic light emitting element 100 according to the present exemplary embodiment of the present disclosure. For example, as illustrated in FIG. 1C, when a plurality of organic light emitting elements include a first element and a second element, the first element can have a configuration of the organic light emitting element 100 according to the present exemplary embodiment of the present disclosure, and in the second element, the first electrode 2 and the conductive layer 11 can contact each other at a position different from the recess portion 110. Specifically, an organic light emitting element alone that emits light with a color having the shortest optical interference distance can have the structure of the organic light emitting element 100 according to the present exemplary embodiment of the present disclosure, and an organic light emitting element other than an organic light emitting element that emits light with a color having the longest optical interference distance can have the structure of the organic light emitting element 100 according to the present exemplary embodiment of the present disclosure. This is because the shorter the optical interference distance of an organic light emitting element is, the thinner the layer thickness of the insulating layer 12 arranged between the first electrode 2 and the conductive layer 11 is, causing the conductive layer 11 accordingly to be more susceptible to a voltage drop of the first electrode 2.

More specifically, when one main pixel includes three subpixels corresponding to a red pixel, a blue pixel, and a green pixel, respectively, the blue pixel alone can have the configuration of the organic light emitting element 100 according to the present exemplary embodiment of the present disclosure, or the red pixel and the green pixel can have the configuration of the organic light emitting element 100 according to the present exemplary embodiment of the present disclosure. In a similar manner, when one main pixel includes two subpixels corresponding to a cyan pixel and a yellow pixel, respectively, the cyan pixel alone can have the configuration of the organic light emitting element 100 according to the present exemplary embodiment of the present disclosure.

FIGS. 1B and 1C illustrate a configuration of the first electrode 2 in which the first element and the second element are isolated from each other, but the configuration is not limited to this. The first electrode 2 can be continuous over the first element and the second element. A configuration in which the conductive layer 11 included in the first element and the conductive layer 11 included in the second element both include the recess portions 110 is employed, but the configuration is not limited to this. A configuration can be employed in which the conductive layer 11 included in the first element includes the recess portion 110, and the conductive layer 11 included in the second element does not include the recess portion 110.

In the conventional organic light emitting element, with the insulating layer 12 arranged between the conductive layer 11 and the first electrode 2, the first electrode 2 contacts the conductive layer 11 outside the recess portion 110, specifically, at an end portion of the conductive layer 11. The area of the connection portion at which the first electrode 2 and the conductive layer 11 contacts each other is determined depending on the layer thickness of the first electrode 2, so that the area has a tendency to be small. As a result, the resistance at the connection portion of the first electrode 2 and the conductive layer 11 tends to be high, presenting a high drive voltage of the conventional organic light emitting element.

On the other hand, as illustrated in FIGS. 1A to 1C, in the organic light emitting element 100 according to the present exemplary embodiment, the first electrode 2 and the conductive layer 11 are electrically connected to each other at least in a part of the recess portion 110. Thus, the area of the connection portion at which the first electrode 2 and the conductive layer 11 contact each other is larger than that in the conventional organic light emitting element. This provides a reduced drive voltage of the organic light emitting element 100 according to the present exemplary embodiment.

In the organic light emitting element 100 according to the present exemplary embodiment, the area in which the first electrode 2 and the conductive layer 11 contact each other can be adjusted with the depth of the recess portion 110. The depth of the recess portion 110 refers to the height between the top surface and the bottom surface of the recess portion 110. For this reason, in the cross section passing through the substrate 1, the insulating layer 12, and the organic compound layer 3, the width of the connection portion at which the first electrode 2 and the conductive layer 11 contact each other is desirably larger than the thickest layer thickness of the first electrode 2. This provides a further reduced drive voltage of the organic light emitting element 100 according to the present exemplary embodiment.

The conventional organic light emitting element has a structure in which the first electrode 2 and the conductive layer 11 contact each other outside the recess portion 110. For this reason, the light emission area decreases by the width (area) in which the first electrode 2 and the conductive layer 11 contact each other outside the recess portion 110.

The light emission area can be the area of a shape (light emitting unit) defined by the insulator portion 5 in a planar view. When the organic light emitting element does not include the insulator portion 5, the light emission area can be the area of a shape (light emitting unit) defined by the recess portion 110.

The first electrode 2 and the conductive layer 11 contact each other within the recess portion 110 in the organic light emitting element 100 according to the present exemplary embodiment, so that the light emission area increases by the area corresponding to the connection portion of the first electrode 2 and the conductive layer 11, which does not need to be provided outside the recess portion 110.

The effect to be exerted on the characteristics of an organic light emitting element by a difference in light emission area will now be described. With a large light emission area of an organic light emitting element, as compared with a case with a small light emission area, a current density for a desired brightness is small. For this reason, an organic light emitting element with a large light emission area is excellent in durability to brightness degradation compared with an organic light emitting element with a small light emission area. Thus, the organic light emitting element 100 according to the present exemplary embodiment is an organic light emitting element excellent also in durability to a brightness degradation ratio.

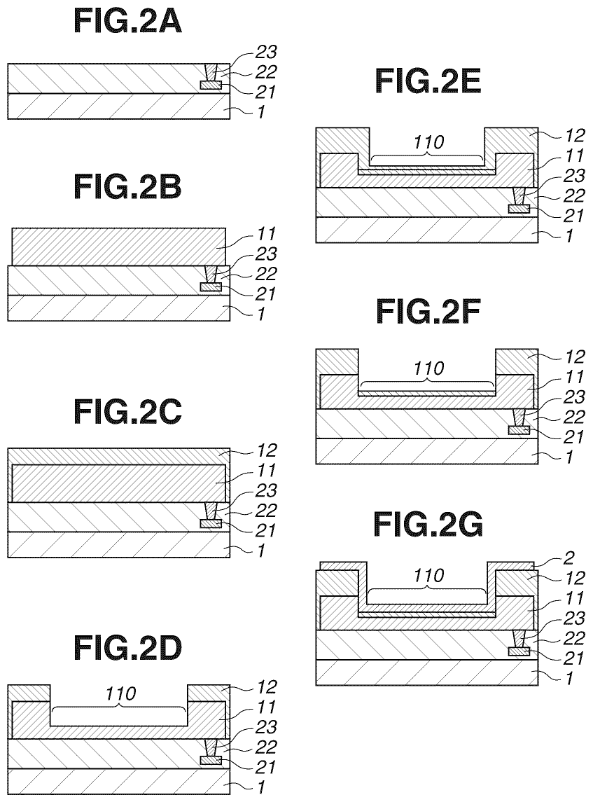

A manufacturing method for the organic light emitting element 100 according to the present exemplary embodiment will now be described with reference to FIGS. 2A to 2G.

First of all, as illustrated in FIG. 2A, the interlayer insulating layer 22 including, for example, the wiring layer 21 is formed on the first surface of the substrate 1. The interlayer insulating layer 22 can be formed using a plasma CVD method or a high-density plasma method, or a combination of these manufacturing methods. After the interlayer insulating layer 22 is formed, the interlayer insulating layer 22 can be subjected to planarization processing that uses a chemical mechanical planarization (CMP) method. After that, an opening is formed at a predetermined position of the interlayer insulating layer 22. The predetermined position can be a position overlapping the wiring layer 21. The opening can be formed using a photolithography method or a dry etching method. A conductive wire 23 is formed in the formed opening. An excess portion can be removed using a CMP method or an etch-back method.

As illustrated in FIG. 2B, the conductive layer 11 is formed on the interlayer insulating layer 22. The conductive layer 11 can be formed using a sputtering method. After the conductive layer 11 is formed, the conductive layer 11 is patterned into a predetermined shape using a photolithography method, a dry etching method, or a wet etching method. Through such a method, the conductive layer 11 connected to the conductive wire 23 can be formed.

As illustrated in FIG. 2C, an insulating film on the conductive layer 11 is formed and then the insulating layer 12 is formed. The insulating layer 12 can be formed using a plasma CVD method.

As illustrated in FIG. 2D, the recess portion 110 is formed in the conductive layer 11. The recess portion 110 can be formed using a photolithography method or a dry etching method. The shape of an end portion of the recess portion 110 is not specifically limited, but the recess portion 110 desirably has a taper shape.

As illustrated in FIG. 2E, the insulating layer 12 is further formed on the conductive layer 11 and the insulating layer 12. The formation method for the insulating layer 12 is similar to the above-described method.

As illustrated in FIG. 2F, the insulating layer 12 is removed using a photolithography method or a dry etching method. In removing the insulating layer 12, it is desirable to set a condition in such a manner that makes the insulating layer 12 remain at least in a part of the bottom surface of the recess portion 110.

As illustrated in FIG. 2G, the first electrode 2 is formed, and a pattern formation is performed using a photolithography method or a dry etching method.

Lastly, by forming the organic compound layer 3 and subsequent layers on the first electrode 2 using a known method, the organic light emitting element 100 is formed.

The above-described manufacturing method provides an organic light emitting element in which the first electrode 2 and the conductive layer 11 are electrically connected to each other at least in a part of the recess portion 110.

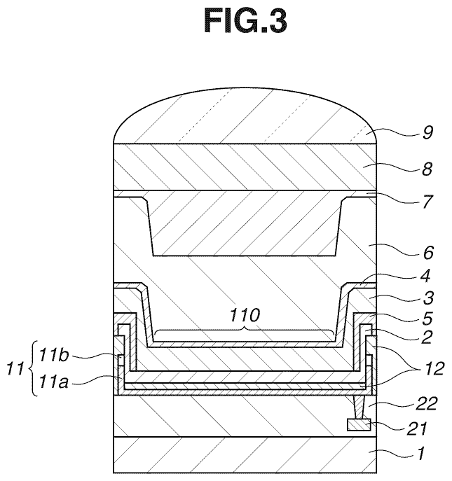

An organic light emitting element according to a second exemplary embodiment will be described with reference to FIG. 3, which is a cross-sectional view illustrating an organic light emitting element according to the present exemplary embodiment. The organic light emitting element according to the present exemplary embodiment differs from that of the first exemplary embodiment in that a conductive layer 11 includes a first conductive layer 11a and a second conductive layer 11b on the first conductive layer 11a. Specifically, the first conductive layer 11a can be a reflective layer and the second conductive layer 11b an antireflection layer.

The first conductive layer 11a can be formed of Al or an alloy material of Al and Cu. Specifically, the material of the first conductive layer 11a can contain 0.2 to 1.0 weight % of Cu in Al. The second conductive layer 11b can be formed of a TiN.

In the organic light emitting element according to the present exemplary embodiment, the recess portion 110 is provided on the first conductive layer 11a. In the recess portion 110, the first electrode 2 is electrically or directly connected to the first conductive layer 11a.

The first conductive layer 11a can be directly connected to the first electrode 2.

The second conductive layer 11b is arranged at an outer periphery of the light emitting unit in the organic light emitting element according to the present exemplary embodiment, so that when the second conductive layer 11b is an antireflection layer, it is possible to prevent light from an adjacent pixel from being reflected on the conductive layer 11 between subpixels and emitted as stray light. For this reason, the organic light emitting element according to the present exemplary embodiment is an organic light emitting element more excellent in color purity.

The organic light emitting element according to the present exemplary embodiment can be formed by forming the first conductive layer 11a and the second conductive layer 11b in this order as the conductive layer 11, and etching a part of the first conductive layer 11a and the second conductive layer 11b.

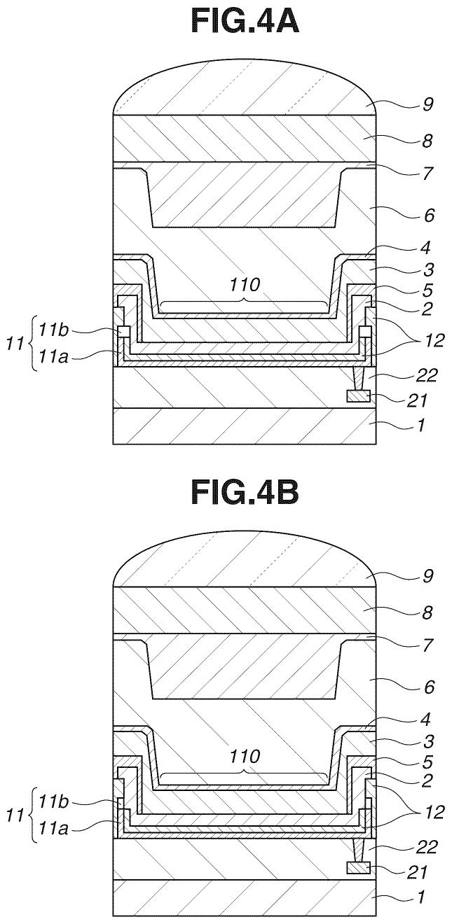

An organic light emitting element according to a third exemplary embodiment will be described with reference to FIGS. 4A and 4B, which are cross-sectional views illustrating the organic light emitting element according to the present exemplary embodiment. The third exemplary embodiment is different in that a conductive layer 11 includes a first conductive layer 11a and a second conductive layer 11b on the first conductive layer 11a, and the insulating layer 12 is arranged between the first electrode 2 and the first conductive layer 11a. In a planar view with respect to the first surface, the second conductive layer 11b in FIG. 4A includes a portion overlapping the first conductive layer 11a and the insulating layer 12, and the second conductive layer 11b in FIG. 4B includes a portion overlapping the first conductive layer 11a alone. It can also be said that, in FIG. 4A, the second conductive layer 11b forms a canopy-shaped structure protruding toward the recess portion 110, with respect to the first conductive layer 11a.

In the present exemplary embodiment, the first conductive layer 11a can be made of an easily-oxidized metal, such as Al, the second conductive layer 11b can be an antireflection layer, and the first electrode 2 can be made of a conductive oxide material, such as an ITO or an IZO. At this time, when the first conductive layer 11a and the first electrode 2 directly contact each other, there is a concern that the first conductive layer 11a is oxidized by the first electrode 2.

In view of the foregoing, in the organic light emitting element according to the present exemplary embodiment, the insulating layer 12 is provided covering the first conductive layer 11a of the second surface 112 of the recess portion 110, and the first electrode 2 and the second conductive layer 11b directly contact each other. Thus, the first electrode 2 and the first conductive layer 11a are arranged via the insulating layer 12, it is possible to prevent the first conductive layer 11a from being oxidized by the first electrode 2. It is, thus, desirable that the first conductive layer 11a and the first electrode 2 do not directly contact each other in the organic light emitting element according to the present exemplary embodiment. Thus, the organic light emitting element according to the present exemplary embodiment is excellent in light emission efficiency because optical interference can be caused more efficiently. The prevention of the first conductive layer 11a from being oxidized by the first electrode 2 achieves further reduction of insulation breakdown of the insulating layer 12 that is attributed to a potential difference between the first electrode 2 and the first conductive layer 11a.

The organic light emitting element according to the present exemplary embodiment can be formed by forming the first conductive layer 11a and the second conductive layer 11b in this order as the conductive layer 11, and etching a part of the first conductive layer 11a and the second conductive layer 11b. At this time, by setting an etching condition in accordance with the type of the material of the first conductive layer 11a, the second conductive layer 11b can be formed into a canopy shape as illustrated in FIG. 4A. In a similar manner, the first conductive layer 11a and the second conductive layer 11b can also be formed in such a manner that a side surface of the first conductive layer 11a and a side surface of the second conductive layer 11b are arranged on a plane as illustrated in FIG. 4B.

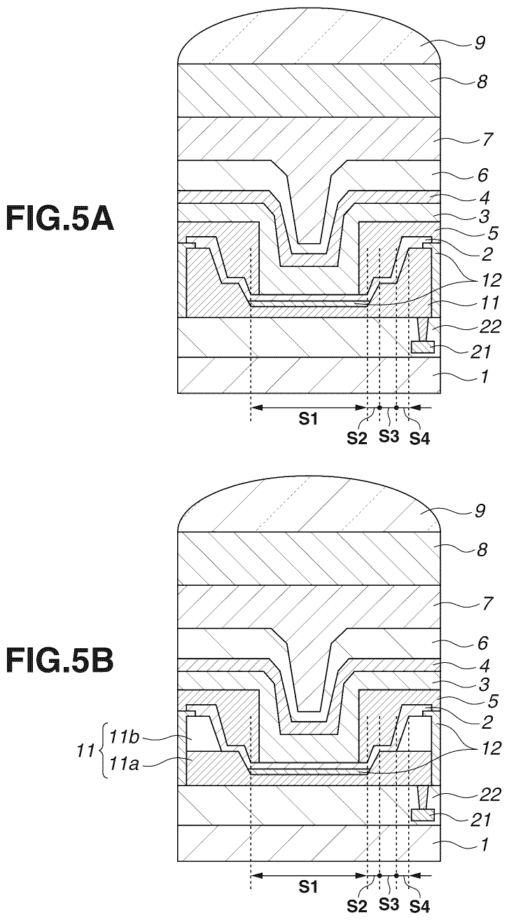

An organic light emitting element according to a fourth exemplary embodiment will be described with reference to FIGS. 5A and 5B, which are cross-sectional views illustrating the organic light emitting element according to the fourth exemplary embodiment. The fourth exemplary embodiment differs from the first exemplary embodiment in that the first electrode 2 has a stepped structure. FIG. 5A illustrates a configuration in which the conductive layer 11 has a single layer structure, and FIG. 5B illustrates a configuration in which the conductive layer 11 consists of the first conductive layer 11a and the second conductive layer 11b.

In the first exemplary embodiment, with the first surface 111 of the recess portion 110 close to the first surface, the first electrode 2 is liable to be easily thinner. Specifically, with the first surface 111 of the recess portion 110 close to the first surface, the first electrode 2 arranged on the end portion of the recess portion 110 is liable to be easily thinner. For this reason, the reliability of the first electrode 2 tends to decline.

In view of the foregoing, the first electrode 2 has a stepped structure in the present exemplary embodiment. Specifically, the first electrode 2 includes a first region S1 in which the first electrode 2 contacts the organic compound layer 3, a second region S2 inclining in the direction getting away from the substrate 1 and contacting the first region S1, a third region S3 having a smaller inclination with respect to the substrate 1 than that of the second region S2 and contacting the second region S2, and a fourth region S4 having a larger inclination with respect to the substrate 1 than that of the third region S3, inclining in the direction getting away from the substrate 1, and contacting the third region S3. With such a configuration, the organic light emitting element according to the present exemplary embodiment can prevent the first electrode 2 from becoming thinner even with a high height between the top surface of the conductive layer 11 and the bottom surface of the recess portion 110 in a direction vertical to the first surface of the substrate 1. The organic light emitting element according to the present exemplary embodiment can thus improve the reliability of the first electrode 2.

By performing etching in such a manner that the conductive layer 11 has a stepped structure in forming the recess portion 110, the organic light emitting element according to the present exemplary embodiment is formed.

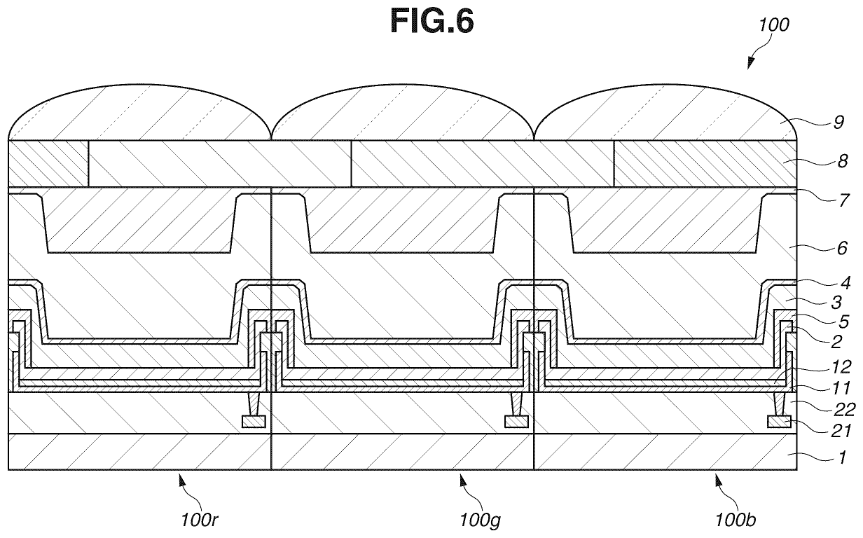

An organic light emitting element 100 according to a fifth exemplary embodiment will be described with reference to FIG. 6, which is a cross-sectional view illustrating the organic light emitting element 100 according to the fifth exemplary embodiment. The organic light emitting element 100 according to the present exemplary embodiment differs from that of the first exemplary embodiment in that the midpoint of the width of the color filter layer 8 arranged over the second electrode 4 is arranged being shifted from the midpoint of the width of its light emitting unit.

The width of the color filter layer 8 refers to the longest width among widths of the color filter layer 8 that are parallel to the first surface in the cross section passing through the substrate 1, the insulating layer 12, and the organic compound layer 3.

When the region of the first electrode 2 that is electrically connected to the organic compound layer 3 is regarded as its light emitting unit, the width of the light emitting unit refers to the longest width among widths of the light emitting unit that are parallel to the first surface. In other words, among widths of the first electrode 2 opened by the insulator portion 5, a width parallel to the first surface. When the organic light emitting element 100 according to the present exemplary embodiment does not include the insulator portion 5, the width of the first electrode 2 arranged in the recess portion 110 can be regarded as the width of the light emitting unit. In other words, the width of the recess portion 110 can be regarded as the width of the light emitting unit.

In the organic light emitting element 100 according to the present exemplary embodiment, by arranging the midpoint of the width of the color filter layer 8 being away by a first distance from the midpoint of the width of the light emitting unit, it is possible to efficiently extract light emitted obliquely to a vertical direction of the first surface.

In a display apparatus including a display region and a peripheral region, a pixel arranged at a position in the display region that is close to the peripheral region desirably has the above-described configuration. By a pixel arranged at a position in the display region that is close to the peripheral region having the configuration according to the present exemplary embodiment, it is possible to improve the image quality of an image to be displayed and observed on the display apparatus.

When the display apparatus includes, in the display region, a first pixel and a second pixel arranged at a position closer to the peripheral region than the first pixel, the distance (second distance) between the midpoint of the width of the color filter layer 8 and the midpoint of the width of the light emitting unit in the second pixel is desirably larger than the distance (first distance) between the midpoint of the width of the color filter layer 8 and the midpoint of the width of the light emitting unit in the first pixel. In a similar manner, when the display apparatus further includes, in the display region, a third pixel arranged at a position closer to the peripheral region than the second pixel, the distance (third distance) between the midpoint of the width of the color filter layer 8 and the midpoint of the width of the light emitting unit in the third pixel is desirably larger than the distance (second distance) between the midpoint of the width of the color filter layer 8 and the midpoint of the width of the light emitting unit in the second pixel. In a pixel arranged at a position closer to the peripheral region, the distance between the midpoint of the width of the color filter layer 8 and the midpoint of the width of the light emitting unit gets larger, making it easier to condense light emitted from the organic light emitting element 100. Thus, the image quality of an image to be displayed and observed on the display apparatus can be improved.

In the present exemplary embodiment, the width of the color filter layer 8 can be the same or vary among subpixels. With varying widths of the color filter layer 8 among subpixels, the width of a color filter through which light with the highest luminosity factor passes is desirably the longest.

When the organic light emitting element 100 according to the present exemplary embodiment further includes the optical member 9, in a view of the cross section passing through the substrate 1, the insulating layer 12, and the organic compound layer 3, the vertex of the optical member 9 can be arranged being shifted from the midpoint of the width of the color filter layer 8. In a view of the cross section passing through the substrate 1, the insulating layer 12, and the organic compound layer 3, the vertex of the optical member 9 can be arranged coinciding with the midpoint of the width of the color filter layer 8.

Such a configuration of the organic light emitting element 100 according to the present exemplary embodiment provides a further improved image quality of images.

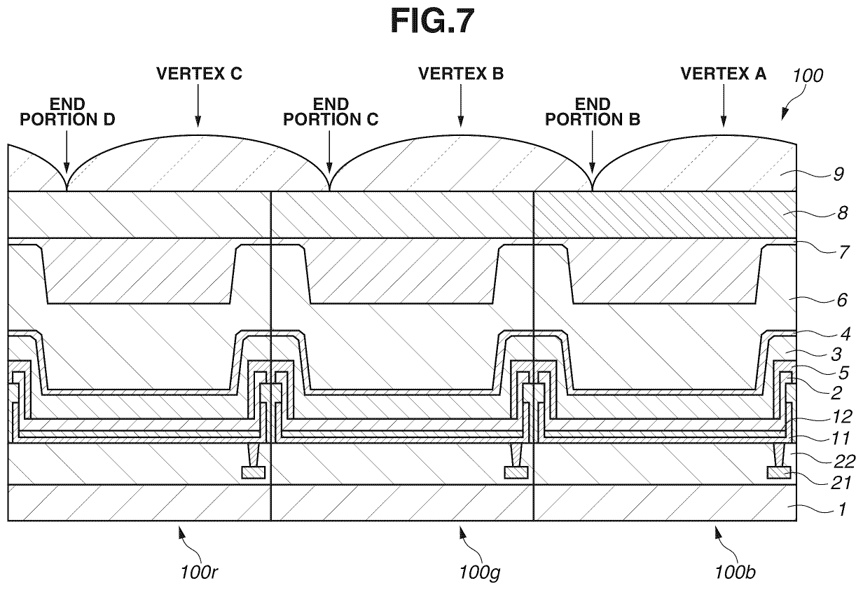

An organic light emitting element 100 according to a sixth exemplary embodiment will be described with reference to FIG. 7, which is a cross-sectional view illustrating the organic light emitting element 100 according to the sixth exemplary embodiment. The organic light emitting element 100 according to the present exemplary embodiment differs from that of the first exemplary embodiment in that the vertex of the optical member 9 arranged on the second electrode 4 is arranged being shifted from the midpoint of the width of the light emitting unit.

The vertex of the optical member 9 refers to a point at which the height of the optical member 9 is highest or lowest between the end portions of the optical member 9 in the cross section passing through the substrate 1, the insulating layer 12, and the organic compound layer 3.

When the optical member 9 has a convex shape curved toward the organic compound layer 3, the vertex of the optical member 9 refers to a point at which the height of the optical member 9 is the lowest between the end portions of the optical member 9. When the optical member 9 has a convex shape curved toward the direction opposite to the organic compound layer 3, the vertex of the optical member 9 refers to a point at which the height of the optical member 9 is highest between the end portions of the optical member 9. Specifically, in FIG. 7, vertices of the optical members 9b, 9g, and 9r included in the respective organic light emitting elements 100b, 100g, and 100r correspond to a vertex A, a vertex B, and a vertex C, respectively.

The end portion of the optical member 9 refers to a point at which the outer edge of the optical member 9 has a minimal value or a maximal value in a cross section passing through the substrate 1, the organic compound layer 3, and the optical member 9. In other words, in FIG. 7, the end portions of the optical member 9g included in the organic light emitting element 100g are end portions B and C, and the end portions of the optical member 9r included in the organic light emitting element 100r are end portions C and D. In this case, the midpoint of the width of an optical member 9 is the midpoint of the line segment connecting the end portions of the optical member 9.

In the present exemplary embodiment, adjacent optical members 9 can contact each other or be separately arranged. When the organic light emitting element 100 according to the present exemplary embodiment includes a first element and a second element with an optical member 9 included in the first element and an optical member 9 included in the second element contacting each other, in the cross section passing through the substrate 1, the insulating layer 12, and the organic compound layer 3, suppose an imaginary line is drawn along the outer edge of the optical member 9 included in the first element. The intersection point of the imaginary line and the color filter layer 8, for example, can be regarded as an end portion of the optical member 9 included in the first element. When the organic light emitting element 100 according to the present exemplary embodiment does not include the color filter layer 8, the intersection point of the imaginary line and the planarization layer 7 can be regarded as an end portion of the optical member 9 included in the first element.

The width of the light emitting unit is similar to that described in the fifth exemplary embodiment.

The vertex of the optical member 9 and the midpoint of the width of the light emitting unit is away from each other by a first distance in the organic light emitting element 100 according to the present exemplary embodiment, making it possible to efficiently extract light emitted obliquely to the vertical direction of the first surface.

In a display apparatus including a display region and a peripheral region, a pixel arranged at a position in the display region that is closer to the peripheral region desirably has the above-described configuration. The above-described configuration of a pixel arranged at a position in the display region that is close to the peripheral region provides an improved image quality of an image to be displayed and observed on the display apparatus.

When the display apparatus includes, in the display region, a first pixel and a second pixel arranged at a position closer to the peripheral region than the first pixel, the distance (second distance) between the vertex of the optical member 9 and the midpoint of the width of the light emitting unit in the second pixel is desirably larger than the distance (first distance) between the vertex of the optical member 9 and the midpoint of the width of the light emitting unit in the first pixel. In a similar manner, when the display apparatus further includes, in the display region, a third pixel arranged at a position closer to the peripheral region than the second pixel, the distance (third distance) between the vertex of the optical member 9 and the midpoint of the width of the light emitting unit in the third pixel is desirably larger than the distance (second distance) between the vertex of the optical member 9 and the midpoint of the width of the light emitting unit in the second pixel. In a pixel arranged at a position closer to the peripheral region, the distance between the vertex of the optical member 9 and the midpoint of the width of the light emitting unit gets larger, making it possible to improve the image quality of an image to be displayed and observed on the display apparatus.

When the organic light emitting element 100 according to the present exemplary embodiment further includes the color filter layer 8, in a view of the cross section passing through the substrate 1, the insulating layer 12, and the organic compound layer 3, the vertex of the optical member 9 can be arranged being shifted from the midpoint of the width of the color filter layer 8. In a view of the cross section passing through the substrate 1, the insulating layer 12, and the organic compound layer 3, the vertex of the optical member 9 can be arranged in such a manner coinciding with the midpoint of the width of the color filter layer 8.

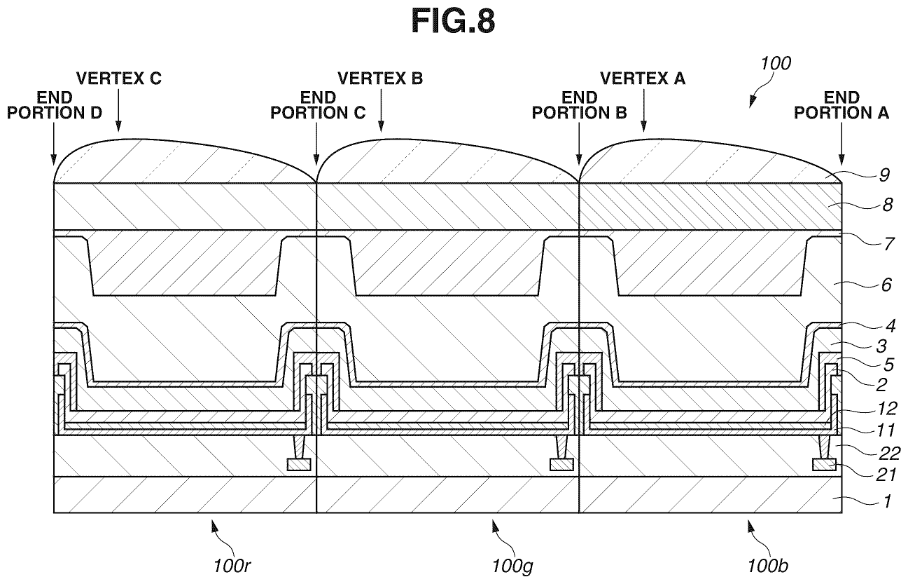

An organic light emitting element 100 according to a seventh exemplary embodiment will be described with reference to FIG. 8, which is a cross-sectional view illustrating the organic light emitting element 100 according to the seventh exemplary embodiment. The organic light emitting element 100 according to the present exemplary embodiment differs from that of the first exemplary embodiment in that the midpoint of the line segment connecting the end portions of an optical member 9 arranged on the second electrode 4 is arranged being shifted from the vertex of the optical member 9.

The end portion of the optical member 9 refers to a point at which the outer edge of the optical member 9 has a minimal value or a maximal value in the cross section passing through the substrate 1, the organic compound layer 3, and the optical member 9. In other words, in FIG. 8, the end portions of the optical member 9b included in the organic light emitting element 100b are end portions A and B. In a similar manner, the end portions of the optical member 9g included in the organic light emitting element 100g are end portions B and C, and the end portions of the optical member 9r included in the organic light emitting element 100r are end portions C and D. In this case, the midpoint of the width of an optical member 9 is the midpoint of the line segment connecting the end portions of the optical member 9.

In the organic light emitting element 100 according to the present exemplary embodiment illustrated in FIG. 8, the midpoint of the line segment connecting the end portions A and B and a vertex A are away from each other (shifted) by a first distance in the cross section passing through the substrate 1, the organic compound layer 3, and the optical member 9. In a similar manner, the midpoint of the line segment connecting the end portions B and C and a vertex B, and the midpoint of the line segment connecting the end portions C and D and a vertex Care shifted in the cross section passing through the substrate 1, the organic compound layer 3, and the optical member 9. This configuration allows efficient extraction of light emitted obliquely to a vertical direction of the first surface.

In a display apparatus including a display region and a peripheral region, a pixel arranged at a position in the display region that is close to the peripheral region desirably has the above-described configuration. By a pixel arranged at a position in the display region that is close to the peripheral region having the above-described configuration, it is possible to improve the image quality of an image to be displayed and observed on the display apparatus.

When the display apparatus includes, in the display region, a first pixel and a second pixel arranged at a position closer to the peripheral region than the first pixel, the distance (second distance) between the midpoint of the line segment connecting the end portions of an optical member 9 and the vertex of the optical member 9 in the second pixel is desirably larger than the distance (first distance) between the midpoint of the line segment connecting the end portions of the optical member 9 and the vertex of the optical member 9 in the first pixel. In a similar manner, when the display apparatus further includes, in the display region, a third pixel arranged at a position closer to the peripheral region than the second pixel, the distance (third distance) between the midpoint of the line segment connecting the end portions of the optical member 9 and the vertex of the optical member 9 in the third pixel is desirably larger than the distance (second distance) between the midpoint of the line segment connecting the end portions of the optical member 9 and the vertex of the optical member 9 in the second pixel. In a pixel arranged at a position getting closer to the peripheral region, the distance between the midpoint of the line segment connecting the end portions of the optical member 9 and the vertex of the optical member 9 gets larger, making it possible to improve the image quality of an image to be displayed and observed on the display apparatus.

In the present exemplary embodiment, adjacent optical members 9 can contact each other or be separately arranged. When the organic light emitting element 100 according to the present exemplary embodiment includes a first element and a second element with an optical member 9 included in the first element and an optical member 9 included in the second element contacting each other, in the cross section passing through the substrate 1, the insulating layer 12, and the organic compound layer 3, suppose an imaginary line is drawn along an outer edge of the optical member 9 included in the first element. The intersection point of the imaginary line and the color filter layer 8, for example, can be regarded as an end portion of the optical member 9 included in the first element. When the organic light emitting element 100 according to the present exemplary embodiment does not include the color filter layer 8, the intersection point of the imaginary line and the planarization layer 7 can be regarded as an end portion of the optical member 9 included in the first element.

When the organic light emitting element 100 according to the present exemplary embodiment further includes the color filter layer 8, in a view of the cross section passing through the substrate 1, the insulating layer 12, and the organic compound layer 3, the vertex of the optical member 9 can be arranged being shifted from the midpoint of the width of the color filter layer 8. In a view of the cross section passing through the substrate 1, the insulating layer 12, and the organic compound layer 3, the vertex of the optical member 9 can be arranged in such a manner as coinciding with the midpoint of the width of the color filter layer 8.

### Application Example

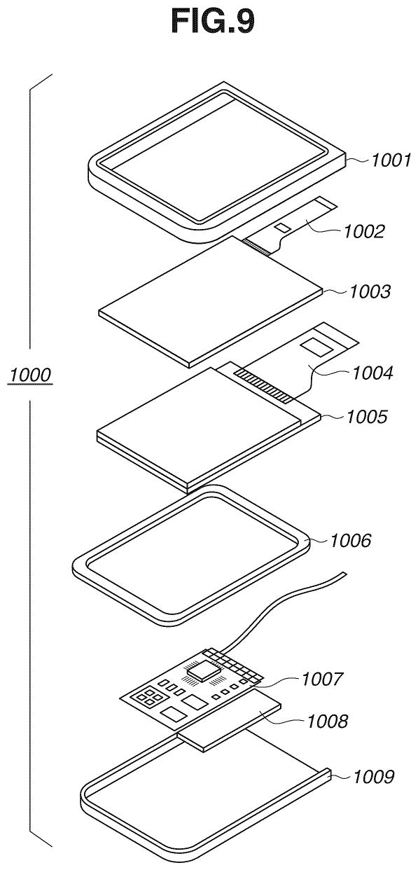

FIG. 9 is a schematic diagram illustrating an example of a display apparatus according to the present exemplary embodiment. A display apparatus 1000 can include a touch panel 1003, a display panel 1005, a frame 1006, a circuit board 1007, and a battery 1008 between an upper cover 1001 and a lower cover 1009. Flexible printed circuit boards (FPCs) 1002 and 1004 are respectively connected to the touch panel 1003 and the display panel 1005. The display panel 1005 can include the organic light emitting element according to the present exemplary embodiment of the present disclosure. Transistors are printed on the circuit board 1007. The battery 1008 can be omitted if the display apparatus 1000 is not a portable device. Even if the display apparatus 1000 is a portable device, the battery 1008 can be provided at another position.

The display apparatus 1000 according to the present exemplary embodiment can include a color filter having a red color, a green color, and a blue color. In the color filter, the red color, the green color, and the blue color can be arranged in the delta array.

The display apparatus 1000 according to the present exemplary embodiment can be used as a display unit of an imaging apparatus including an image sensor that receives light. The imaging apparatus can include a display unit that displays information acquired by the image sensor. The display unit can be a display unit exposed to the outside of the imaging apparatus, or a display unit arranged within its viewfinder. The imaging apparatus can be a digital camera or a digital video camera.

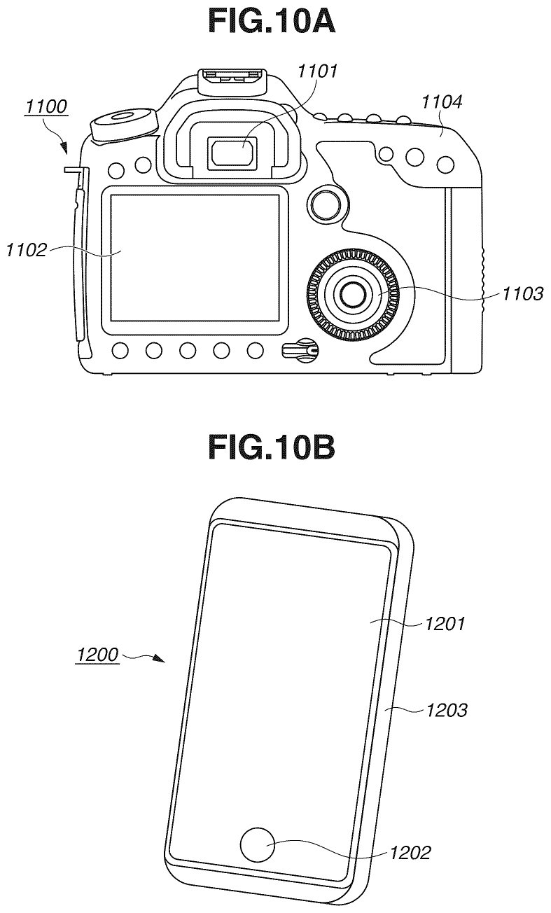

FIG. 10A is a schematic diagram illustrating an example of an imaging apparatus according to the present exemplary embodiment. An imaging apparatus 1100 can include a viewfinder 1101, a back-surface display 1102, an operation unit 1103, and a housing 1104. The viewfinder 1101 and the back-surface display 1102 can include the organic light emitting element according to the present exemplary embodiment of the present disclosure. In this case, the display apparatus can display captured images as well as environmental information and image capturing instructions. The environmental information can include the intensity and the orientation of external light, a speed at which a subject moves, and the possibility of a subject being shielded with a shielding object.

The imaging apparatus 1100 can further include an optical unit (not illustrated). The optical unit can include a single lens or a plurality of lenses that form(s) an image onto an image sensor accommodated in the housing 1104. By adjusting relative positions of the plurality of lenses, it is possible to control a focal point. This operation can also be performed automatically. The imaging apparatus can be called a photoelectric conversion apparatus. As an image capturing method, the photoelectric conversion apparatus can include a method of detecting a difference from a previous image and a method of clipping an image from constantly-recorded images, instead of sequentially capturing images.

FIG. 10B is a schematic diagram illustrating an example of an electronic device according to the present exemplary embodiment. An electronic device 1200 includes a display unit 1201, an operation unit 1202, and a housing 1203. The display unit 1201 can include the organic light emitting element according to the present exemplary embodiment of the present disclosure. The housing 1203 can include circuitry, printed circuit boards including the circuitry, a battery, and a communication unit. The operation unit 1202 can be a button or a touch panel type response unit. The operation unit 1202 can be a biometric authentication unit that unlocks the electronic device 1200 by recognizing a fingerprint. The electronic device 1200 including a communication unit can also be called a communication device. The electronic device 1200 can further have a camera function by including a lens and an image sensor. An image captured using the camera function is displayed on the display unit 1201.

Examples of the electronic device 1200 include a smartphone and a laptop personal computer.

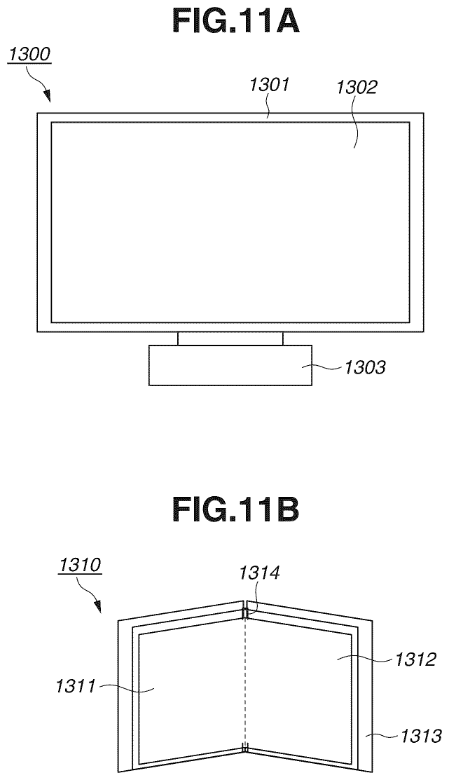

FIGS. 11A and 11B are schematic diagrams each illustrating an example of a display apparatus according to the present exemplary embodiment. FIG. 11A illustrates a display apparatus, such as a television monitor or a personal computer (PC) monitor. A display apparatus 1300 includes a housing 1301 and a display unit 1302. The light emitting element according to the present exemplary embodiment of the present disclosure can be used in the display unit 1302.

The display apparatus 1300 further includes a base 1303 supporting the housing 1301 and the display unit 1302. The shape of the base 1303 is not limited to the shape illustrated in FIG. 11A. The lower side of the housing 1301 can also serve as a base.

The housing 1301 and the display unit 1302 can have a curved shape. The curvature radius of the curved shape can be between 5000 mm and 6000 mm.

FIG. 11B is a schematic diagram illustrating another example of the display apparatus according to the present exemplary embodiment. A display apparatus 1310 illustrated in FIG. 11B has a foldable configuration, and is a so-called foldable display apparatus. The display apparatus 1310 includes a first display unit 1311, a second display unit 1312, a housing 1313, and a folding point 1314. The first display unit 1311 and the second display unit 1312 can include the organic light emitting element according to the present exemplary embodiment of the present disclosure. The first display unit 1311 and the second display unit 1312 can form a seamless one display apparatus. The first display unit 1311 and the second display unit 1312 can be divided at the folding point 1314. The first display unit 1311 and the second display unit 1312 can individually display different images or one image in cooperation.

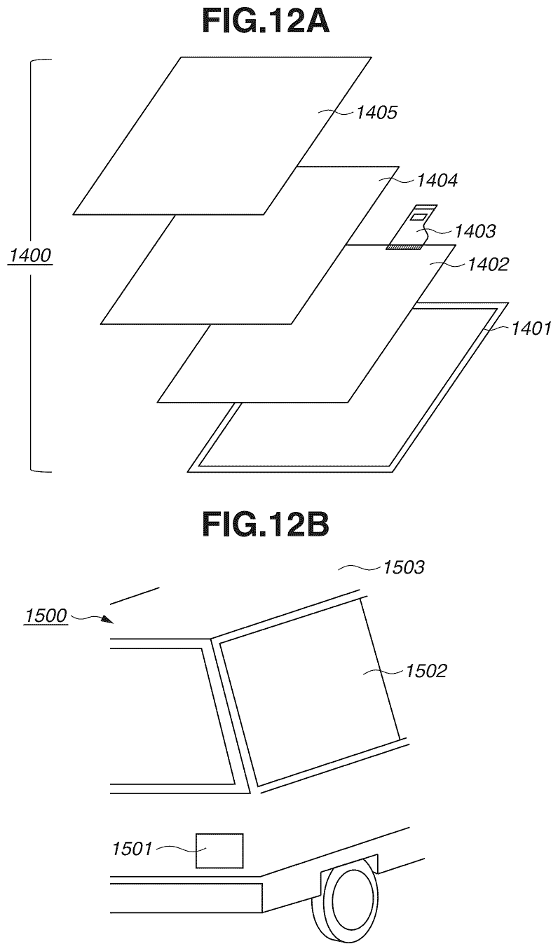

FIG. 12A is a schematic diagram illustrating an example of an illumination apparatus according to the present exemplary embodiment. An illumination apparatus 1400 can include a housing 1401, a light source 1402, and a circuit board 1403. The light source 1402 can include the organic light emitting element according to the present exemplary embodiment of the present disclosure. The illumination apparatus 1400 can include an optical film 1404 to enhance the color rendering index of the light source 1402. The illumination apparatus 1400 can also include a light diffusion unit 1405 to effectively diffuse light of the light source 1402. The illumination apparatus 1400 including the light diffusion unit 1405 makes it possible to deliver light to a wide range. The optical film 1404 and the light diffusion unit 1405 can be provided nearer the surface of light emission of illumination. A cover can be provided as appropriate at the outermost portion.

The illumination apparatus 1400 is an apparatus that illuminates the inside of a room, for example. The illumination apparatus 1400 can emit light in a white color, a daylight white color, or other colors from blue to red. The illumination apparatus 1400 can include a light control circuit for controlling these colors. The illumination apparatus 1400 can include a power circuit. The power circuit can be a circuit that converts alternating-current voltage into direct-current voltage. In addition, the color temperature of the white color is 4200 K and the color temperature of the daylight white color is 5000 K. The illumination apparatus 1400 can include a color filter.

The illumination apparatus 1400 according to the present exemplary embodiment can also include a heat release unit. The heat release unit releases heat in the apparatus to the outside of the apparatus, and is made of a metal or ceramic with high thermal conductivity.

FIG. 12B is a schematic diagram illustrating an automobile serving as an example of a movable body according to the present exemplary embodiment. The automobile includes a tail lamp serving as an example of a lighting device. An automobile 1500 can include a tail lamp 1501, and can be configured to light the tail lamp 1501 when a brake operation is performed. The automobile 1500 can include a vehicle body 1503 and a window 1502 attached to the vehicle body 1503.

The tail lamp 1501 can include the organic light emitting element according to the present exemplary embodiment of the present disclosure. The tail lamp 1501 can include a protection member that protects a light source. The material of the protection member is not limited as long as the protection member is transparent and has a certain high level of strength, but it is desirable that the protection member is formed of polycarbonate. A furandicarboxylic acid derivative or an acrylonitrile derivative can be mixed with polycarbonate.

The movable body according to the present exemplary embodiment includes either or both a drive force generation unit that generates drive force to be mainly used for the movement of the movable body or/and a rotator to be mainly used for the movement of the movable body. The drive force generation unit can be an engine or a motor, for example. The rotator can be a tire, a wheel, a screw of a ship, or a propeller of a flight vehicle, for example. Specifically, the movable body can be a bicycle, an automobile, an electric train, a ship, an airplane, or a drone. The movable body can include a fuselage and a lighting device provided on the fuselage. The lighting device can emit light to let a user know the position of the fuselage.

The electronic device or the display apparatus can be applied to a system that can be worn as a wearable device, such as smart glasses, a head-mounted display, or a smart contact lens, for example. The electronic device can include an imaging apparatus that can photoelectrically convert visible light, and a display apparatus that can emit visible light.

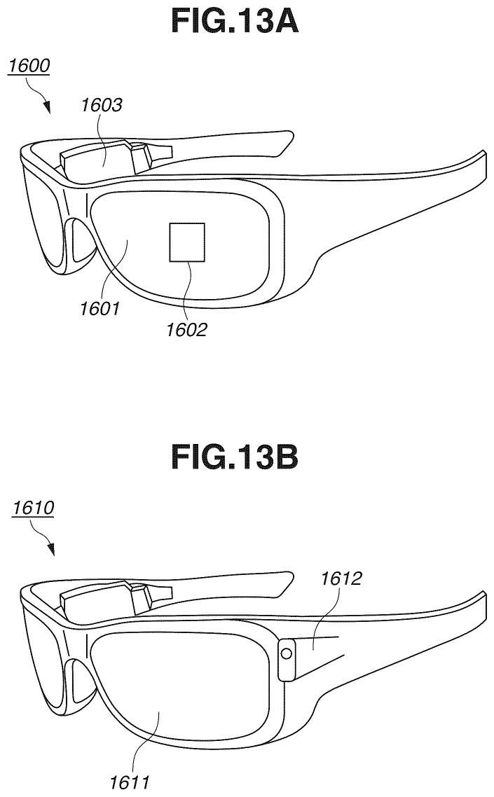

FIGS. 13A and 13B are schematic diagrams each illustrating an example of eyeglasses (smart glasses) according to the present exemplary embodiment. Eyeglasses 1600 (smart glasses) will be described with reference to FIG. 13A. The eyeglasses 1600 include a display unit on the back surface of a lens 1601. The display unit can include the organic light emitting element according to the present exemplary embodiment of the present disclosure. Furthermore, an imaging apparatus 1602 including a complementary metal-oxide semiconductor (CMOS) sensor or a single photon avalanche diode (SPAD) can be provided on the front surface of the lens 1601.

The eyeglasses 1600 further include a control apparatus 1603. The control apparatus 1603 can include one or more processors, circuitry, or combinations thereof and can function as a power source that supplies power to the imaging apparatus 1602 and the display unit. The control apparatus 1603 can also control operations of the imaging apparatus 1602 and the display device. In the lens 1601, an optical system for condensing light in the imaging apparatus 1602 and the display device is formed.

Eyeglasses 1610 (smart glasses) will be described with reference to FIG. 13B. The eyeglasses 1610 include a control apparatus 1612, and the control apparatus 1612 is provided with a display apparatus including the organic light emitting element according to the present exemplary embodiment of the present disclosure. The control apparatus 1612 can further include an imaging apparatus equivalent to the imaging apparatus 1602. In a lens 1611, an optical system for projecting light emitted from the control apparatus 1612 is formed, and an image is projected onto the lens 1611. The control apparatus 1612 functions as a power source that supplies power to the imaging apparatus and the display apparatus, and controls operations of the imaging apparatus and the display apparatus. The control apparatus 1612 can include a visual line detection unit that detects a visual line of a wearer. Infrared light can be used in the detection of a visual line. An infrared light emission unit emits infrared light onto an eyeball of a user looking at a displayed image. An imaging unit including a light receiving element detects reflected light of the emitted infrared light that is reflected from the eyeball. Thus, a captured image of the eyeball is obtained. By including a reduction unit for reducing light from the infrared light emission unit to a display unit in a planar view, a decline in image quality is reduced.

From a captured image of an eyeball obtained by image capturing using infrared light, the control apparatus 1612 detects the visual line of a user with respect to a displayed image. A known method can be used in visual line detection that uses a captured image of an eyeball. As an example, a visual line detection method can be used that is based on a Purkinje image obtained by the reflection of irradiation light on a cornea.

More specifically, visual line detection processing that is based on the pupil center corneal reflection is performed. By calculating an eye vector representing the orientation (rotational angle) of an eyeball, based on an image of a pupil and a Purkinje image that are included in a captured image of the eyeball, using the pupil center corneal reflection, the visual line of a user is detected.

The display apparatus according to an exemplary embodiment of the present disclosure can include an imaging apparatus including a light receiving element, and control a displayed image on the display apparatus based on visual line information on the user from the imaging apparatus.

Specifically, in the display apparatus, a first eyeshot region viewed by the user, and a second eyeshot region other than the first eyeshot region are determined based on the visual line information. The first eyeshot region and the second eyeshot region can be determined by a control apparatus of the display apparatus, or the first eyeshot region and the second eyeshot region determined by an external control apparatus can be received. In a display region of the display apparatus, the display resolution in the first eyeshot region can be controlled to be higher than the display resolution in the second eyeshot region. In other word, the resolution in the second eyeshot region can be lower than the resolution in the first eyeshot region.

Artificial intelligence (AI) can be used to determine the first eyeshot region and a region with high priority. The AI can be a model configured to estimate the angle of a visual line, and the distance to a target existing far along the visual line, from an image of an eyeball using training data including an image of an eyeball, and the direction in which the eyeball in the image actually gives a gaze. The AI can be included in the display apparatus, in the imaging apparatus, or in an external device. In a case where an external device includes the AI, the AI can be desirably applied to smart glasses further including an imaging apparatus that captures images of the outside. The smart glasses can display captured images indicating external information in real time.

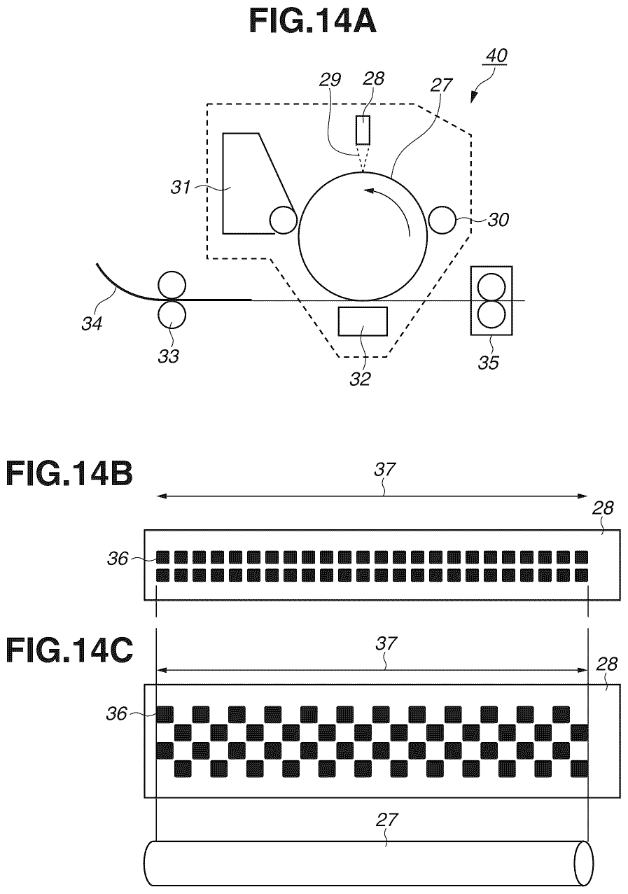

FIG. 14A is a schematic diagram illustrating an example of an image forming apparatus according to the present exemplary embodiment. An image forming apparatus 40, which is an electrophotographic image forming apparatus, includes a photosensitive member 27, an exposure light source 28, a charging unit 30, a development unit 31, a transfer device 32, a conveyance roller 33, and a fixing device 35. Light 29 is emitted from the exposure light source 28, forming an electrostatic latent image on the surface of the photosensitive member 27. The exposure light source 28 can include the organic light emitting element according to the present exemplary embodiment. The development unit 31 includes toner. The charging unit 30 charges the photosensitive member 27. The transfer device 32 transfers a developed image onto a recording medium 34. The conveyance roller 33 conveys the recording medium 34. The recording medium 34 is paper, for example. The fixing device 35 fixes an image formed on the recording medium 34 to the recording medium.

FIGS. 14B and 14C are diagrams illustrating the exposure light source 28, and are schematic diagrams illustrating a state in which a plurality of light emitting units 36 are arranged on an elongated substrate. An arrow 37 indicates a column direction in which organic light emitting elements are arrayed. This column direction is the same as the direction of the axis around which the photosensitive member 27 rotates. This direction can also be called a long axis direction of the photosensitive member 27. FIG. 14B illustrates a configuration in which the light emitting units 36 are arranged in the long axis direction of the photosensitive member 27. FIG. 14C illustrates a configuration, different from the configuration illustrated in FIG. 14B, in which the light emitting units 36 are alternately arranged in the column direction on first and second columns. The first and second columns are arranged at different positions in the row direction.

A plurality of light emitting units 36 are arranged at intervals on the first column. The second column includes light emitting units 36 at positions corresponding to the intervals between the light emitting units 36 on the first column. That is, a plurality of light emitting units 36 are arranged at intervals also in the row direction. The arrangement illustrated in FIG. 14C can be rephrased as a state in which light emitting units 36 are arranged in a grid, in a houndstooth pattern, or a checkered pattern, for example.

As described above, the use of an apparatus that employs the organic light emitting element according to the present exemplary embodiment provides stable display for a long time with good image quality.

As described above, the organic light emitting element according to any of the exemplary embodiments of the present disclosure can reduce the voltage drop of a lower electrode due to a close distance between the connection portion between the lower electrode and the reflective electrode and a light emitting unit. The organic light emitting element according to any of the exemplary embodiments of the present disclosure can also reduce a rise in drive voltage due to a large area in which the lower electrode and the reflective electrode contact each other. In addition, the lower electrode and the reflective electrode contact each other within a recess portion, making larger the light emission area in a planar view in the organic light emitting element according to any of the exemplary embodiments of the present disclosure than that in the conventional organic light emitting element.

According to any of the exemplary embodiments of the present disclosure, an organic light emitting element with a reduced voltage drop of a lower electrode can be provided.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of priority from Japanese Patent Application No. 2023-090274, filed May 31, 2023, which is hereby incorporated by reference herein in its entirety.

What is claimed is:

1. An organic light emitting element comprising:
a substrate having a first surface;
a conductive layer on the first surface;
an insulating layer;
a first electrode;
an organic compound layer; and
a second electrode, in this order,
wherein the conductive layer includes a recess portion, and
wherein the first electrode and the conductive layer are electrically connected to each other at least in a part of the recess portion.

2. The organic light emitting element according to claim 1, wherein the first electrode and the conductive layer are directly connected to each other at least in a part of the recess portion.

3. The organic light emitting element according to claim 1, wherein the first electrode and the conductive layer are directly connected to each other at least in a part of a side surface of the recess portion.

4. The organic light emitting element according to claim 1, wherein the conductive layer is continuously formed in the recess portion.

5. The organic light emitting element according to claim 1, wherein the first electrode is a transparent electrode.

6. The organic light emitting element according to claim 1,
wherein the conductive layer includes a first conductive layer and a second conductive layer, and
wherein the second conductive layer is provided at a position closer to the first electrode than the first conductive layer.

7. The organic light emitting element according to claim 6, wherein the recess portion is provided in the first conductive layer.

8. The organic light emitting element according to claim 6, wherein the first electrode is directly connected to the second conductive layer.

9. The organic light emitting element according to claim 6, wherein the first electrode is not directly connected to the first conductive layer.

10. The organic light emitting element according to claim 6, wherein the second conductive layer has a portion overlapping the first conductive layer and the insulating layer.

11. The organic light emitting element according to claim 1,
wherein the organic light emitting element includes a first element and a second element configured to emit light in wavelengths different from each other;
wherein the organic light emitting element includes an insulating layer between the conductive layer and the first electrode, and
wherein, when the insulating layer included in the first element is regarded as a first insulating layer, and the insulating layer included in the second element is regarded as a second insulating layer, in a cross section passing through the substrate, the insulating layer, and the organic compound layer, a height vertical to the first surface of the first insulating layer and a height vertical to the first surface of the second insulating layer are different from each other.

12. The organic light emitting element according to claim 11,
wherein the organic light emitting element further includes a third element configured to emit light in a wavelength different from those of the first element and the second element,
wherein the organic light emitting element includes an insulating layer between the conductive layer and the first electrode, and
wherein, when the insulating layer included in the third element is regarded as a third insulating layer, in a cross section passing through the substrate, the insulating layer, and the organic compound layer, a height vertical to the first surface of the first insulating layer, a height vertical to the first surface of the second insulating layer, and a height vertical to the first surface of the third insulating layer are different from each other.

13. The organic light emitting element according to claim 1, wherein the first electrode includes a first region contacting the organic compound layer, a second region inclining in a direction getting away from the substrate, and contacting the first region, a third region having inclination with respect to the substrate smaller than that of the second region, and contacting the second region, and a fourth region having inclination with respect to the substrate larger than that of the third region, inclining in a direction getting away from the substrate, and contacting the third region.

14. The organic light emitting element according to claim 1, wherein the organic light emitting element includes a color filter or an optical member on the second electrode.

15. The organic light emitting element according to claim 14,
wherein the organic light emitting element includes a color filter on the second electrode,
wherein, in a cross section passing through the substrate, the insulating layer, and the organic compound layer, when a longest width among widths of the color filter that are parallel to the first surface is regarded as a width of the color filter, a region of the first electrode that is electrically connected to the organic compound layer is regarded as a light emitting unit, and a longest width among widths of the light emitting unit that are parallel to the first surface is regarded as a width of the light emitting unit, a midpoint of the width of the color filter and a midpoint of the width of the light emitting unit are away from each other by a first distance.

16. The organic light emitting element according to claim 14,
wherein the organic light emitting element includes an optical member on the second electrode,
wherein, in a cross section passing through the substrate, the insulating layer, and the organic compound layer, when a region of the first electrode that is electrically connected to the organic compound layer is regarded as a light emitting unit, and a longest width among widths of the light emitting unit that are parallel to the first surface is regarded as a width of the light emitting unit, a vertex of the optical member and a midpoint of the width of the light emitting unit are away from each other by a first distance.

17. The organic light emitting element according to claim 14,
wherein the organic light emitting element includes an optical member on the second electrode,
wherein, in a cross section passing through the substrate, the insulating layer, and the organic compound layer, when a point at which an outer edge of the optical member has a minimal value or a maximal value is regarded as an end portion of the optical member, a midpoint of a line segment connecting end portions of the optical member and a vertex of the optical member are away from each other by a first distance.

18. A photoelectric conversion apparatus comprising:
an image sensor configured to receive light; and
a display unit configured to display an image captured by the image sensor,
wherein the organic light emitting element according to claim 1 is the display unit.

19. A display apparatus comprising:
a display unit including the organic light emitting element according to claim 1; and
a housing on which the display unit is provided.

20. An electronic device comprising:
a display unit including the organic light emitting element according to claim 1;
a housing on which the display unit is provided; and
a communication unit that is provided in the housing and is configured to communicate to outside.

21. An illumination apparatus comprising:
a light source including the organic light emitting element according to claim 1; and
a housing on which the light source is provided.

22. A movable body comprising:
a lighting device including the organic light emitting element according to claim 1; and
a fuselage on which the lighting device is provided.

23. A wearable device comprising:
a display unit including the organic light emitting element according to claim 1;
an optical system configured to condense light in the display unit; and
a control apparatus configured to control an operation of the display unit.

24. An image forming apparatus comprising:
a photosensitive member; and
an exposure light source configured to expose the photosensitive member,
wherein the exposure light source includes the organic light emitting element according to claim 1.
